(19) United States
(12) Patent Application Publication
(10) Pub. No.: US 2002/0068405 A1
(43) Pub. Date: Jun. 6, 2002

(54) Fabrication method for a semiconductor integrated circuit device

(76) Inventor: Atsuki Ono, Tokyo (JP)

Correspondence Address: McGinn & Gibb, PLLC, Suite 200, 8321 Old Courthouse Road, Vienna, VA, 22182-3817, US

(21) Appl. No.: 09/988,321

(22) Filed: Nov. 19, 2001

(30) Foreign Application Priority Data
Nov. 30, 2000 (JP) 2000-365447

(51) Int. Cl. H01L 21/8234

(52) U.S. Cl. 438/275

(57) ABSTRACT

A method is disclosed for fabricating a semiconductor integrated circuit device in which first pMOS transistors having a gate insulation film composed of a silicon oxide film are mounted together with second pMOS transistors having a gate insulation film composed of a silicon oxide-nitride film that is thinner than the silicon oxide film; wherein an impurity is implanted in advance in a polysilicon layer that is grown on the surfaces of the silicon oxide film and the silicon oxide-nitride film in only those positions at which second pMOS transistors are to be formed before patterning the polysilicon layer into gate electrodes. The polysilicon layer is then patterned to form gate electrodes, following which the gate electrodes and silicon substrate are each implanted with impurity to form source-drain regions.

### BACKGROUND OF THE INVENTION

1. Field of the Invention

The present invention relates to a method of fabricating a semiconductor integrated circuit device in which p-channel MOS (Metal Oxide semiconductor) transistors (hereinbelow abbreviated as pMOS) having a gate insulation film composed of a silicon oxide-nitride film are mounted together with pMOS transistors having a gate insulation film composed of a silicon oxide film that is thicker than the silicon oxide-nitride film.

2. Description of the Related Art

Semiconductor integrated circuit devices are currently being used for a wide variety of uses, and various fabrication methods have been proposed for manufacturing these semiconductor integrated circuit devices. The procedure described hereinbelow is a typical technique known in the art for forming transistor elements of MOS structure on such semiconductor integrated circuit devices.

The surface of a silicon substrate is first subjected to thermal oxidation to grow a gate insulation film, and on this surface, a polysilicon layer that is to constitute gate electrodes is then formed by a CVD (Chemical Vapor Deposition) method. A photoresist is next formed on the polysilicon layer, the photoresist is patterned to a desired shape by photolithography, and the gate electrodes are formed by etching away the polysilicon layer.

An oxide film is then grown on the silicon substrate by a thermal CVD method so as to cover the gate electrodes, following which side walls are formed on the side surfaces of the gate electrodes by an etchback process using a dry etching method.

An impurity is then implanted in the gate electrode and silicon substrate under prescribed conditions using the sidewalls and gate electrode as a mask. The implanted impurity ions are then activated by an annealing process to form the source-drain regions in the silicon substrate, thereby completing the MOS transistor.

In an MOS transistor that is formed by the above-described typical fabrication method, the diffusion of impurity ions must be deep in the gate electrode, while the diffusion of impurity ions in the source-drain region must be shallow.

If the depth of diffusion of impurity ions in the source-drain region is given priority, the depth of diffusion in the gate electrode becomes insufficient, the gate electrode is depleted, and the characteristics of the MOS transistor deteriorate. In particular, boron (B), which is the impurity that is implanted in the source-drain region of a pMOS transistor, has lower solid solubility than arsenic (As) or phosphorus (P), which are the impurities that are implanted in the source-drain region of a nMOS transistor, and the above-described depletion of the gate electrode is therefore marked.

Techniques for preventing the depletion of the gate electrode have been proposed in, for example, “High Performance Transistors with State-of-the-Art CMOS Technologies” (Seungheon Song, et al., IEDM 99, p. 427) in which impurity is implanted into the polysilicon layer that is to become the gate electrode before patterning (hereinbelow referred to as “pre-doping”).

By pre-doping the impurity in this way and then patterning the polysilicon layer, depletion of the gate electrode can be prevented.

However, when implanting impurity into the silicon substrate to form the source-drain region as previously described, the same impurity is simultaneously implanted in the polysilicon layer that is to become the gate electrode. The amount of impurity in the polysilicon layer therefore becomes excessive when the above-described pre-doping is effected in the polysilicon layer, with the result that the impurity ions that are diffused in the annealing process may penetrate the gate insulation film from the polysilicon layer and reach as far as the silicon substrate. This effect is particularly pronounced when boron is used as the impurity ion to form a pMOS transistor and is a cause for such phenomena as fluctuation in the threshold voltage and deterioration of the characteristics of the MOS transistor.

A technique has been developed for forming the gate insulation film from silicon oxide-nitride instead of silicon oxide in order to prevent the penetration and diffusion of boron as far as the silicon substrate. Forming the gate insulation film of a pMOS transistor from silicon oxide-nitride, however, causes the problem of NBTI (Negative Bias Temperature Instability).

NBTI is a phenomenon in which the energy of positive holes that are implanted in the interface between the gate electrode and gate insulation film when a negative bias voltage is applied to a pMOS transistor causes the hydrogen that terminates silicon atoms to become hydrogen ions having a positive charge, and these hydrogen ions are in turn trapped by nitrogen atoms to become positive fixed charges, which has the unwanted effect of boosting the threshold voltage. This effect is described in detail in, for example, “NBTI enhancement by nitrogen incorporation into ultra-thin gate oxide for 0.10 μm gate CMOS generation” (N. Kimizuka, et al., 2000 Symposium on VLSI Technology Digest of Technical Papers).

In other words, if pre-doping is carried out when forming a pMOS transistor to prevent the deterioration of characteristics that is caused by depletion of gate electrodes, a choice must be made between forming the gate insulation film from silicon oxide and allowing the deterioration in characteristics that is caused by the penetration of boron, or forming the gate insulation film from silicon oxide-nitride and allowing the degradation of life expectancy that is caused by NBTI.

However, semiconductor integrated circuit devices of recent years are progressing from devices having only the simple functions of CPU, logic circuits, and memory devices and toward system-on-chip devices in which all of these functions are loaded on a single chip that constitutes a system.

Since different performance is demanded for each function in this type of semiconductor integrated circuit device, a plurality of types of transistor elements each operated by different power supply voltages are mounted together. For example, some constructions include: an I/O (Input/Output) circuit unit that includes a step-down circuit that reduces the power supply voltage that is supplied from the outside; and logic circuit units that operate by the low voltage that is generated in the I/O circuit unit.

Because the I/O circuit unit operates by a high-voltage dc power supply voltage that is supplied from the outside, the gate insulation film of MOS transistors is formed thick for the purpose of reducing gate leak current. The logic circuit unit, on the other hand, operates by the low voltage that is supplied from the I/O circuit unit, and the gate insulation film of MOS transistors is therefore thin.

In a pMOS transistor, the degradation of life expectancy due to NBTI is generally more pronounced with higher operating voltage. In a semiconductor integrated circuit device in which an I/O circuit unit and a logic circuit unit are mounted together, the MOS transistors of the I/O circuit unit that operate at high voltage use a gate insulation film of a thick silicon oxide film to reduce the degradation of life expectancy and the MOS transistors of the logic circuit unit that operate at low voltage use a gate insulation film of thin silicon oxide-nitride film to reduce the deterioration of characteristics.

Referring now to FIGS. 1-8, an explanation is presented regarding a method of the prior art for fabricating a semiconductor integrated circuit device having an I/O circuit unit and a logic circuit unit as described hereinabove.

As shown in FIG. 1, semiconductor integrated circuit device 100 is a construction having I/O block 101 that operates at high voltage and core unit 102 that operates at low voltage. Core unit 102 is a construction that includes: SRAM block 103, which is a memory device; high-speed logic block 104, which is a logic circuit that operates at high speed; and low-speed logic block 105, which is a logic circuit that operates at low speed.

As shown in FIG. 2, first transistor 111, which is a pMOS transistor of I/O block 101, is provided with silicon oxide film 113, which is a thick gate insulation film; while second transistor 112, which is a pMOS transistor of core unit 102, is provided with silicon oxide-nitride film 114, which is a thin gate insulation film.

First transistor 111 and second transistor 112 are constructions in which silicon oxide film 113 or silicon oxide-nitride film 114 is first formed on the surface of n-type silicon substrate 115, over which a polysilicon layer that is to form gate electrode 116 is then stacked. Sidewalls 117 are then formed on silicon oxide film 113 and the side surfaces of gate electrode 116 as well as on silicon oxide-nitride film 114 and the side surfaces of gate electrode 116.

Source-drain regions 118 are formed in the surface layer of silicon substrate 115 that is located at the outer side of sidewalls 117 and extension regions 119 are formed in the surface layer of silicon substrate 115 that is located at the inner sides of source-drain regions 118 with channel regions 120 interposed between source-drain regions 118 and extension regions 119.

An n-type semiconductor is used in silicon substrate 115 because only the pMOS transistors that are relevant to this proposal are given as an example of first transistor 111 and second transistor 112, but n-type silicon substrate 115 here referred to may also be an n-well region that is formed in a p-type silicon substrate.

As described in the foregoing explanation, core unit 102 is made up by a plurality of blocks each serving various functions, and the film thickness of the gate insulation film of the MOS transistors that are included in each of these blocks may differ accordingly.

The gate insulation films of the pMOS transistors of I/O block 101, however, are formed thicker than the gate insulation films of the pMOS transistors of any of the blocks of core unit 102.

Explanation next regards a method of the prior art for fabricating semiconductor integrated circuit device 100 in which first transistors 111, in which the above-described gate insulation film is composed of a silicon oxide film, are mounted together with second transistor 112, in which the gate insulation film is composed of a silicon oxide-nitride film.

First, as shown in FIG. 3(a), STI (Shallow Trench Isolation) is formed at prescribed positions of n-type silicon substrate 115 using a known method to form element isolation regions for separating each transistor, following which silicon oxide film 113 is grown over the entire surface of silicon substrate 115 to a thickness of approximately 5.0 nm as shown in FIG. 3(b).

Next, as shown in FIG. 3(c), photoresist 132 is formed on the upper surface of silicon oxide film 113 at the position where first transistor 111 is to be formed, and silicon oxide film 113 at the position where second transistor 112 is to be formed that is exposed from photoresist 132 is removed by wet etching.

Silicon oxide film 113 thus remains only at the position of first transistor 111, and, after removing photoresist 132 from the surface, silicon oxide-nitride film 114, which is thinner than silicon oxide film 113, is grown on the surface of silicon substrate 115 to a thickness of approximately 2.0 nm at positions of formation of second transistor 112 by effecting thermal oxy-nitriding over the entire surface of silicon substrate 115 in a mixed atmosphere of nitrogen (N2) and oxygen (O2), as shown in FIG. 3(d).

This nitrogen (N2) and oxygen (O2) also acts on silicon oxide film 113, but silicon oxide film 113 has already undergone oxidation and is little affected by oxy-nitriding. In addition, thick silicon oxide film 113 is for the most part not penetrated by these gases, and a silicon oxide-nitride layer therefore does not form below silicon oxide film 113.

As shown in FIG. 3(e), polysilicon layer 133, which is to become the gate electrodes 116 of first transistor 111 and second transistor 112, is next grown on the surfaces of silicon oxide film 113 and silicon oxide-nitride film 114 to a film thickness of approximately 150 nm by a CVD method.

P-type impurity ions are then pre-doped in polysilicon layer 133 by I/I (Ion Implantation), as shown in FIG. 3(f).

Since pMOS transistors are formed as first transistor 111 and second transistor 112 in this example, boron ions are implanted under the conditions of 3 keV and 4×10¹⁵ atms/cm². If nMOS transistors (not shown in the figures) are formed, impurity ions such as phosphorus ions are implanted under the conditions of 10 keV and 4×10¹⁵ atms/cm².

After completion of pre-doping, a photoresist 134 is formed on the surface of polysilicon layer 133, and, as shown in FIG. 3(g), photoresist 134 is patterned by photolithography and polysilicon layer 133 is then removed by etching to leave a prescribed shape and thus form the gate electrodes 116 of each of first transistor 111 and second transistor 112. Gate electrodes 116 are formed with a gate length of, for example, 0.25 μm for first transistor 111 and 0.1 μm for second transistor 112.

Next, as shown in FIG. 3(h), photoresist 134 is removed and boron ions are implanted in gate electrodes 116 and extension regions 119 of silicon substrate 115, following which sidewalls 117 are formed on the side surfaces of gate electrodes 116 as shown in FIG. 3(i).

Then, as shown in FIG. 3(j), boron ions are implanted, under the same conditions as employed in pre-doping, into gate electrodes 116 and the outer side of sidewalls 117 that are to form source-drain regions 118 of first transistor 111 and second transistor 112.

Finally, the implanted boron ions are activated by an annealing process to form source-drain regions 118 in silicon substrate 115, thereby completing each of first transistor 111 and second transistor 112.

In first transistor 111 and second transistor 112 that have been formed in this way, a shallow diffusion can be achieved because the boron ions are implanted into source-drain regions 118 only one time, while a deep diffusion of boron ions into gate electrodes 116 can be achieved because two implantations of boron ions are carried out.

In addition, first transistor 111 is provided with silicon oxide film 113 that is a thick gate insulation film, and the life expectancy of the transistor is therefore not impaired despite application of high voltage. Similarly, second transistor 112 is provided with silicon oxide-nitride film 114 that is a thin gate insulation film and the transistor is therefore capable of operation at high speed and with excellent characteristics even at low voltage.

As shown in FIG. 4A, it has been confirmed by the inventors of the present invention that the ON current-OFF current characteristic of second transistor 112 of core block 102 in which gate electrodes 116 have been pre-doped is improved over a case in which pre-doping is not carried out.

FIG. 4B, shows the ON current-OFF current characteristic of an nMOS transistor of core block 102, this characteristic also showing an improvement for a case in which pre-doping is performed over a case in which pre-doping is not performed. As shown in FIGS. 4A and 4B, the difference in the ON current-OFF current characteristic according to the presence of a pre-doping step is less significant in a pMOS transistor than in an nMOS transistor, but this difference tends to increase in the activation annealing process that follows ion implantation of the source-drain region.

If, from the CV (Capacitance Voltage) characteristic of second transistor 112, which is provided with silicon oxide-nitride film 114 in which the gate insulation film is thin, capacitance is converted to the film thickness of a silicon oxide film, the film thickness is 2.64 nm (26.4 Å) when the voltage is −1.2 V as shown in FIG. 5A, this change representing an improvement over 2.70 nm (27 Å) for a case in which pre-doping is not performed. FIG. 5B shows the CV characteristic of an nMOS transistor of core block 102 when the voltage is +1.2 V, and in this case as well, the thickness is 2.51 nm (25.1 Å) when pre-doping is performed, an improvement over 2.65 nm (26.5 Å) when pre-doping is not performed.

If capacitance is converted to film thickness from the CV characteristic of first transistor 111, in which the gate insulation film is composed of thick silicon oxide film 113, the film thickness is 4.48 nm (44.8 Å) when the voltage is −1.2 V as shown in FIG. 6A, this being an improvement over 4.59 nm (44.8 Å) for a case in which pre-doping is not carried out. FIG. 6B shows the CV characteristic of an nMOS transistor of I/O block 101 when the voltage is +1.2 V. In this case as well, the film thickness is 4.25 nm (42.5 Å) when pre-doping has been carried out, this being an improvement over 4.39 nm (43.9 Å) for a case in which pre-doping is not carried out.

Nevertheless, as shown in FIG. 6, the curve of the CV characteristic is displaced by pre-doping in first transistor 111 in which the gate insulation film is made from thick silicon oxide film 113, the threshold voltage being displaced to the low potential side.

This displacement occurs because the gate insulation film of first transistor 111 is silicon oxide film 113, and as shown in FIG. 7, the boron of gate electrode 116 is therefore assumed to diffuse as far as channel region 120 of silicon substrate 115 in the annealing process that follows ion implantation of the source-drain region.

The inventors of the present invention have found that the ON/OFF current characteristic of first transistor 111, in which gate electrode 116 has been pre-doped, is worse than a case in which pre-doping is not carried out, as shown in FIG. 8.

### SUMMARY OF THE INVENTION

It is therefore an object of the present invention to provide a fabrication method for fabricating a semiconductor integrated circuit device having improved characteristics in which first transistors of pMOS structure having a gate insulation film that is composed of a silicon oxide film are mounted together with second transistors of pMOS structure having a gate insulation film that is composed of a silicon oxide-nitride film that is thinner than the silicon oxide film.

To achieve the above-described object in the present invention, an impurity is implanted in only the positions of the polysilicon layer in which the second transistors are to be formed before the polysilicon layer that is grown on a silicon oxide film and silicon oxide-nitride film is patterned into gate electrodes. The polysilicon layer is then patterned and gate electrodes formed, and impurity is implanted into each of the gate electrodes and silicon substrate to form the source-drain region.

By adopting this approach, the use of silicon oxide-nitride film in the gate insulation film of the second transistors prevents the deterioration in characteristics that is caused by the diffusion of impurity at the time of the annealing process for activation. Furthermore, the implantation of impurity both before and after patterning the gate electrodes that are composed of polysilicon ensures sufficient implantation of impurity and prevents deterioration of characteristic due to depletion.

On the other hand, the use of a thick silicon oxide film for the gate insulation film in the first transistor limits the degradation of life expectancy due to NBTI despite operation at high voltage. Finally, because excessive impurity is not implanted in the gate electrodes that are composed of polysilicon, impurity does not penetrate the gate insulation film and diffuse as far as the silicon substrate at the time of the annealing process for activation, and deterioration of characteristics due to impurity diffusion can thus be prevented.

The above and other objects, features, and advantages of the present invention will become apparent from the following description based on the accompanying drawings, which illustrate examples of preferred embodiments of the present invention.

### BRIEF DESCRIPTION OF THE DRAWINGS

FIG. 1 is a plan view showing an example of the circuit layout of a semiconductor integrated circuit device of the prior art;

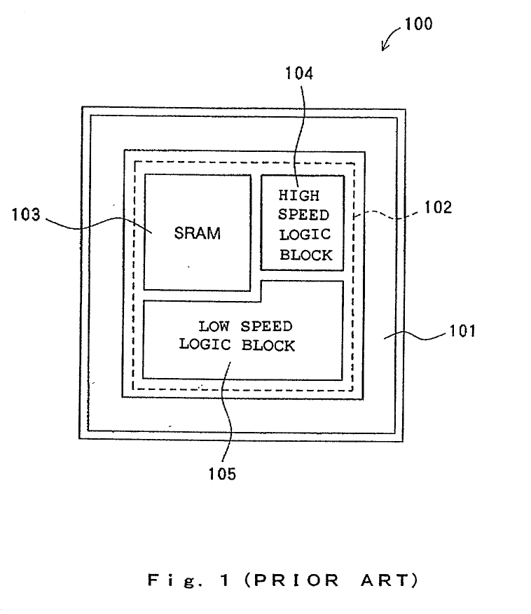

FIG. 2 is a side section showing the construction of a semiconductor integrated circuit device of the prior art;

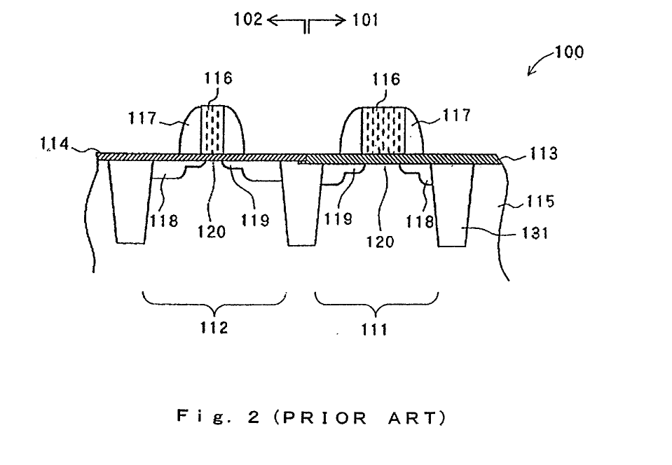

FIG. 3 is a process chart showing the procedures of a fabrication method of a semiconductor integrated circuit device of the prior art;

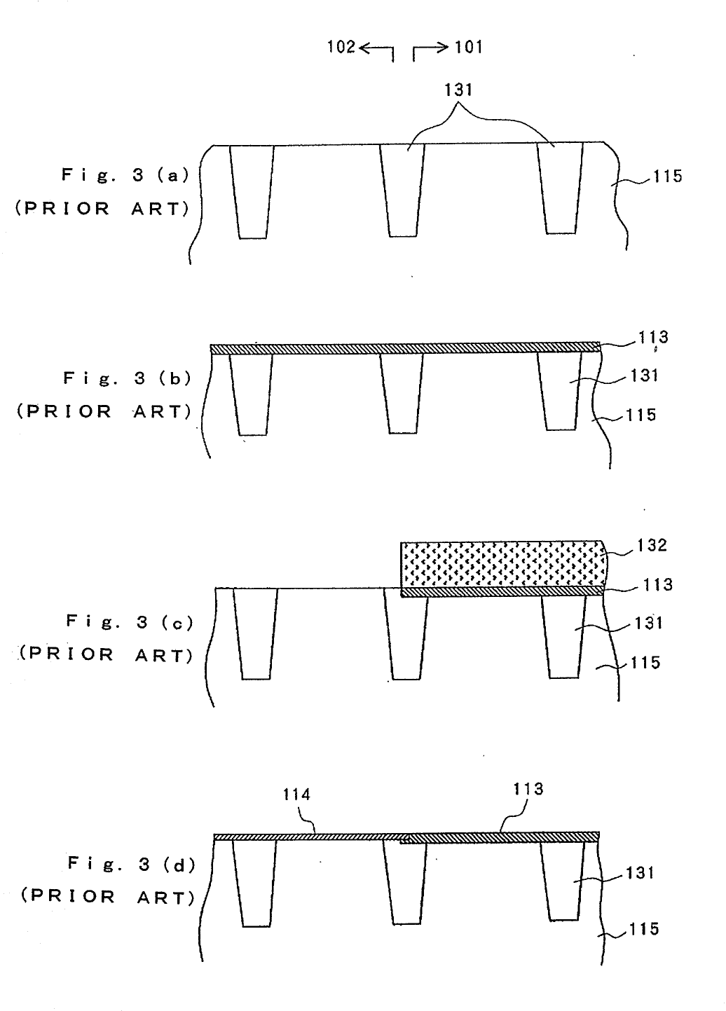

FIG. 4 is a graph showing the change in the ON/OFF current characteristic that results in cases of using and not using pre-doping in an MOS transistor of the core block shown in FIG. 1;

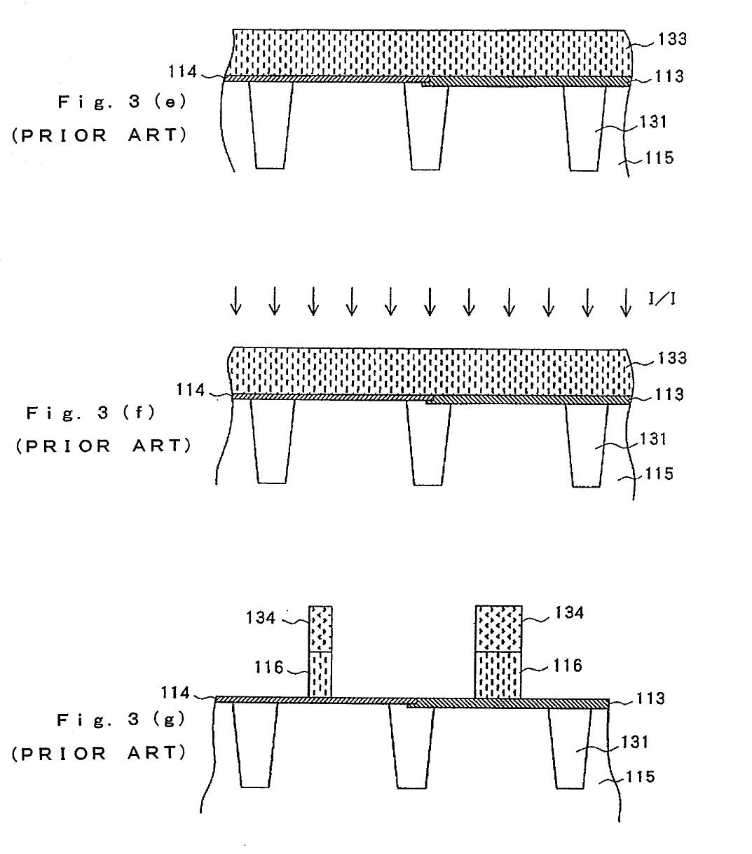

FIG. 5 is a graph showing the change in the CV characteristic that results from cases of using and not using pre-doping in an MOS transistor of the core block shown in FIG. 1;

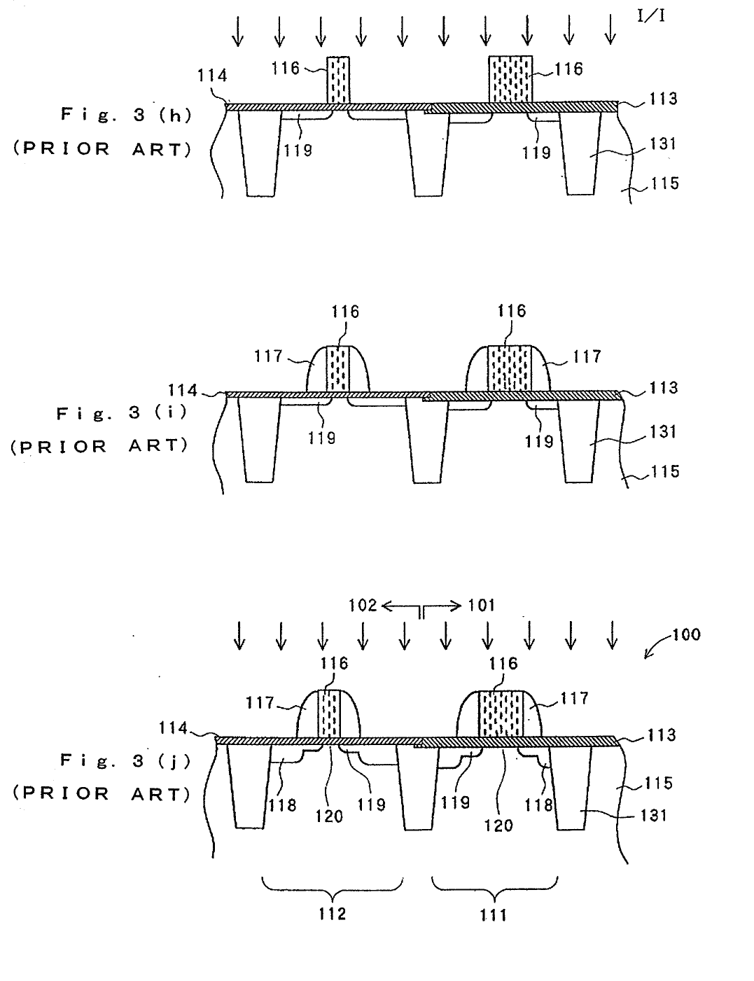

FIG. 6 is a graph showing the change in the CV characteristic that results from cases of using and not using pre-doping in an MOS transistor of the I/O block shown in FIG. 1;

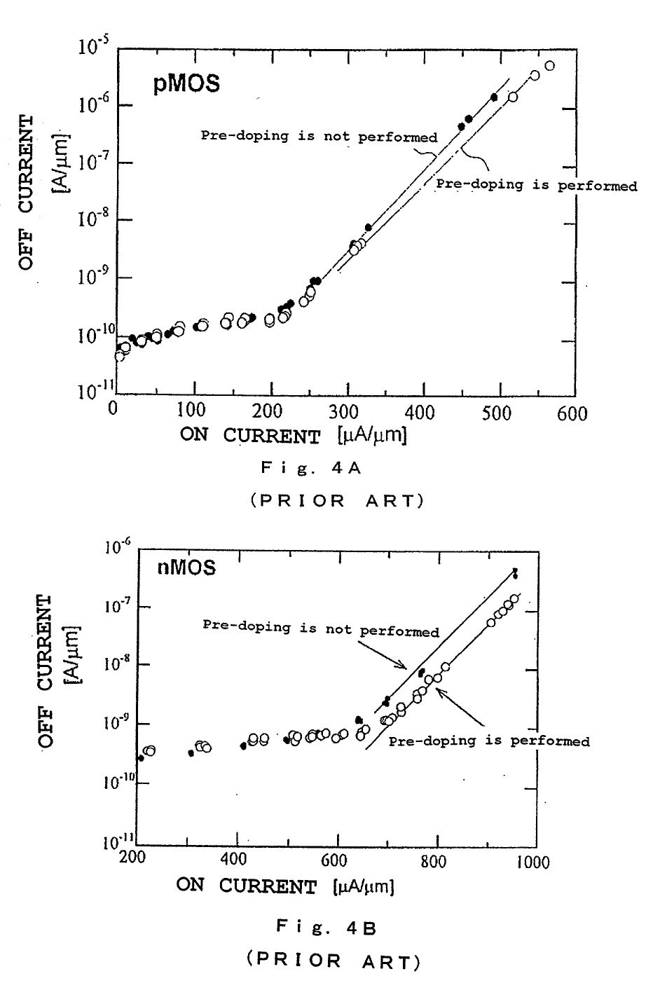

FIG. 7 is a schematic view showing the penetration of a gate insulation film by impurity in the first transistor;

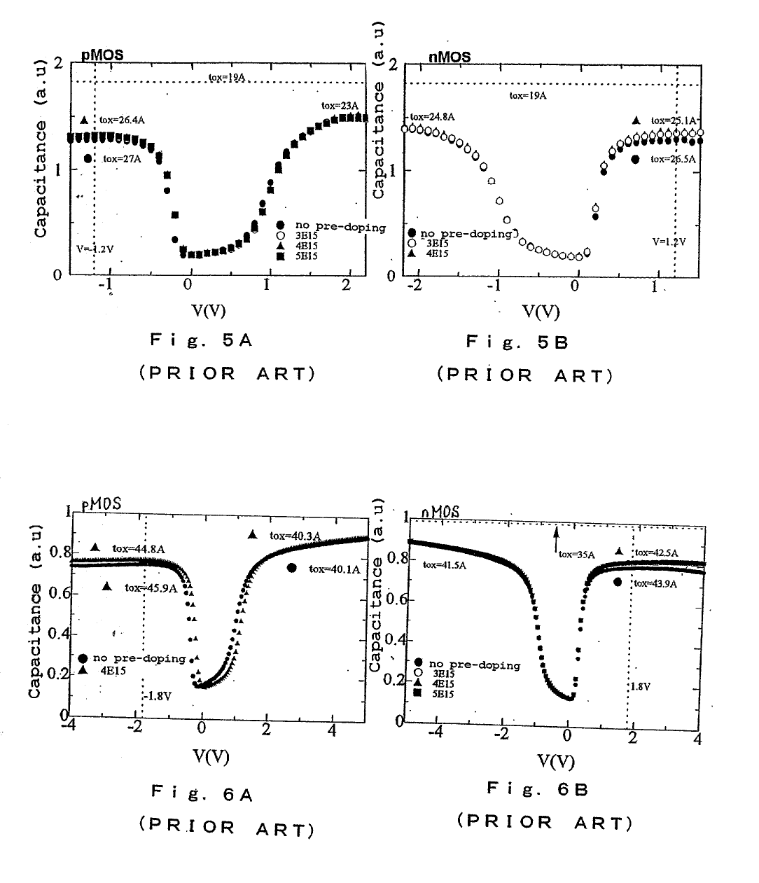

FIG. 8 is a graph showing the change in the ON/OFF current characteristic that results from cases of using and not using pre-doping in an MOS transistor of the I/O block shown in FIG. 1; and

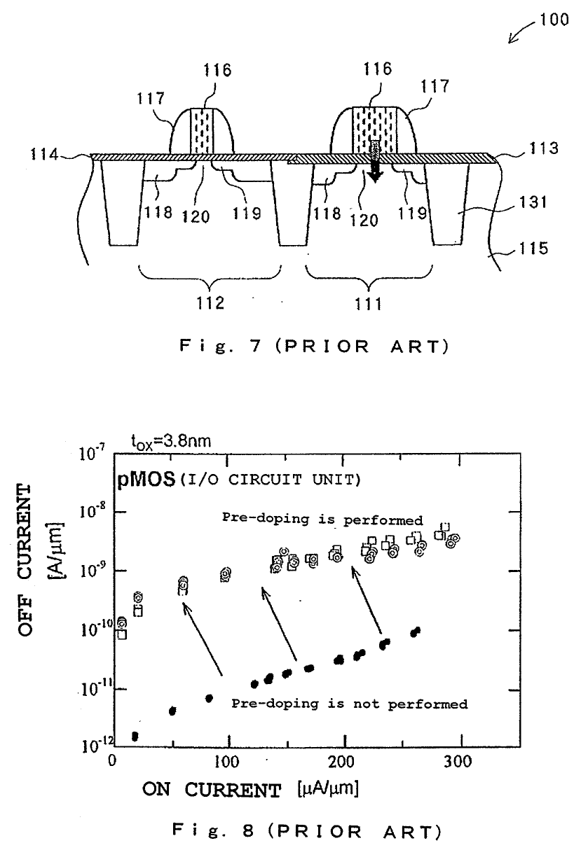

FIG. 9 is a process chart showing the procedures of a fabrication method of a semiconductor integrated circuit device of the present invention.

### DETAILED DESCRIPTION OF THE PREFERRED EMBODIMENTS

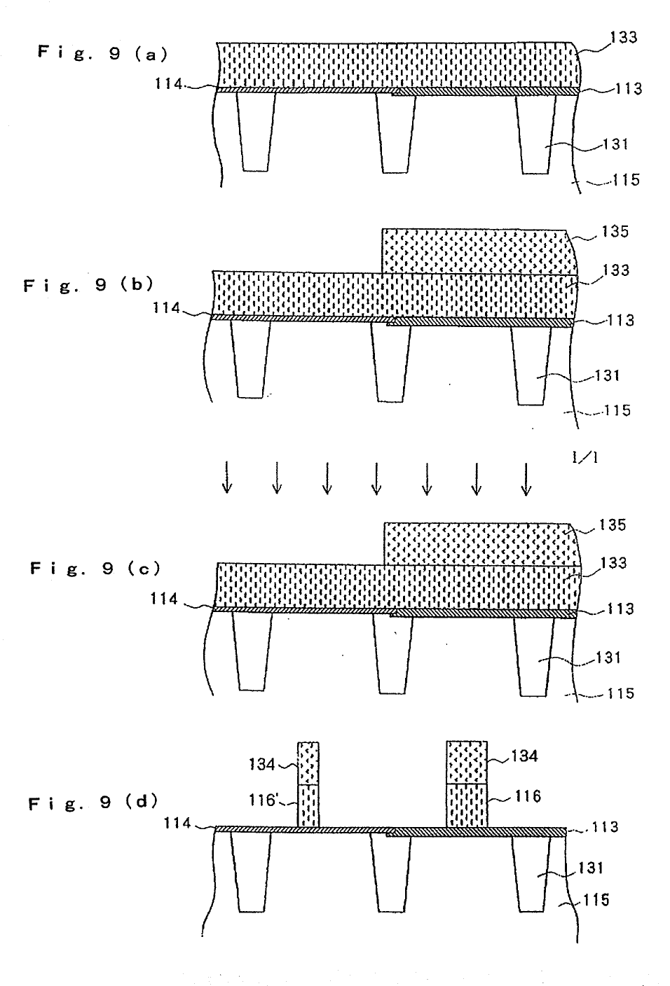

Referring now to FIG. 9, the fabrication method of a semiconductor integrated circuit device of the present invention is explained.

Regarding procedures that are identical to those of the previously described fabrication method of a semiconductor integrated circuit device of the prior art, the same names and reference numerals are used for the embodiment of the present invention and detailed explanation is omitted.

In the fabrication method for a semiconductor integrated circuit device of this embodiment as well, semiconductor integrated circuit device 100 of the same construction as in the prior art is fabricated. However, due to differences in portions of the fabrication steps in semiconductor integrated circuit device 100 that is fabricated by the fabrication method of the present embodiment, the amount of impurity of gate electrode 116 of first transistor 111 is approximately half that of second transistor 112 and boron ions that are implanted in gate electrode 116 of first transistor 111 do not diffuse as far as channel region 120 of silicon substrate 115 at the time of the annealing process.

In the present embodiment, as in the fabrication method of the semiconductor integrated circuit device of the prior art, silicon oxide film 113 is first grown uniformly over the entire surface of n-type silicon substrate 115 to a film thickness of approximately 5.0 nm, following which silicon oxide film 113 is removed from the formation position of second transistor 112.

Silicon oxide-nitride film 114 is next grown to a thickness of approximately 2.0 nm on the surface of silicon substrate 115 at the formation position of second transistor 112, and as shown in FIG. 9(a), polysilicon layer 133 that is to become the gate electrodes is grown to a film thickness of approximately 150 nm on the surfaces of silicon oxide film 113 and silicon oxide-nitride film 114 by a CVD method.

The next step is the pre-doping of boron ions in polysilicon layer 133. In the present embodiment, photoresist 135 is formed at the formation position of first transistor 111 as shown in FIG. 9(b), following which polysilicon layer 133 on silicon oxide-nitride film 114 that is left exposed by photoresist 135 is subjected to boron implantation under the conditions of 3 keV and 4×10¹⁵ atms/cm².

After completion of pre-doping, photoresist 135 is removed and polysilicon layer 133 is patterned to a prescribed shape by means of photolithography as shown in FIG. 9(d) to form gate electrode 116 of first transistor 111 and gate electrode 116′ of second transistor 112.

Subsequently, as in the fabrication method of a semiconductor integrated circuit device of the prior art, boron ions are uniformly implanted in gate electrodes 116 and 116′ and extension regions 119 of silicon substrate 115, sidewalls 117 are formed, and boron ions are implanted into gate electrodes 116 and 116′ and the outer sides of sidewalls 117 under the same conditions as in pre-doping. The boron ions are then activated by an annealing process to form source-drain regions 118 in silicon substrate 115.

As in the method of the prior art, the fabrication method of a semiconductor integrated circuit device of the present embodiment as described in the foregoing explanation allows implantation of a sufficient amount of impurity in gate electrode 116′ in second transistor 112 and therefore can prevent the deterioration in characteristic caused by depletion of gate electrode 116′ and further, allows excellent high-speed operation at low voltage.

Furthermore, the constitution of the gate insulation film of second transistor 112 by silicon oxide-nitride film 114 prevents the diffusion of boron ions that are implanted in gate electrode 116′ into channel region 120 in the annealing process for activation of the source-drain region that follows ion implantation and therefore prevents the deterioration of characteristic that results from such diffusion.

In comparison to the prior art, an excess of impurity is not implanted in gate electrode 116 of first transistor 111, and boron ions that have been implanted in gate electrode 116 therefore do not diffuse as far as channel region 120 of silicon substrate 115 in the annealing process for activation that is applied to the source-drain regions after ion implantation, and deterioration in characteristics that is caused by diffusion is thus prevented.

Moreover, the constitution of the gate insulation film by thick silicon oxide film 113 in first transistor 111 limits deterioration in life expectancy caused by NBTI despite operation at high voltage.

Although depletion of gate electrode 116 in first transistor 111 cannot be prevented, first transistor 111 having a thick gate insulation film is generally operated at high voltage and the influence of deterioration of characteristics caused by depletion of gate electrode 116 therefore does not present a problem.

In addition, although the deterioration in life expectancy that is caused by NBTI cannot be prevented in second transistor 112, in which the gate insulation film is constituted by a silicon oxide-nitride film, second transistor 112 having a thin gate insulation film is generally operated at low voltage and the effect of deterioration of life expectancy that is caused by NBTI therefore does not present a particular problem.

The present invention is not limited to the above-described form, and various modifications are permissible within the scope of the invention. For example, although a case was described in the above explanation in which boron ions were used as the implanted impurity, boron fluoride ions (BF₂) may also be employed.

While a preferred embodiment of the present invention has been described using specific terms, such description is for illustrative purposes only, and it is to be understood that changes and variations may be made without departing from the spirit or scope of the following claims.

What is claimed is:

1. A fabrication method of a semiconductor integrated circuit device in which a first pMOS transistor having a gate insulation film composed of a silicon oxide film is mounted together with a second pMOS transistor having a gate insulation film composed of a silicon oxide-nitride film that is thinner than said silicon oxide film, said fabrication method comprising the steps of:
forming a polysilicon layer that is to become the gate electrodes of said first pMOS transistor and said second pMOS transistor on the surfaces of said silicon oxide film and said silicon oxide-nitride film;
implanting a prescribed amount of an impurity into portions of said polysilicon layer other than the formation position of said first pMOS transistor;
patterning said polysilicon layer in the shape of said gate electrodes; and
implanting a prescribed amount of impurity into each of said polysilicon layer that has undergone patterning and regions of a silicon substrate that are to become source-drain regions of said first pMOS transistor and said second pMOS transistor.

2. The fabrication method of a semiconductor integrated circuit device according to claim 1, wherein said impurity is mainly boron ions.
